(19) United States
(12) Patent Application Publication
(10) Pub. No.: US 2026/0004861 A1
(43) Pub. Date: Jan. 1, 2026

(54) LEVEL-BASED PROGRAMMING WITH MULTIPLE ANALOG PROGRAM VERIFY OPERATIONS BETWEEN PROGRAMMING PULSES

(71) Applicant: Micron Technology, Inc., Boise, ID (US)

(72) Inventors: Huai-Yuan Tseng, San Ramon, CA (US); Eric Nien-Heng Lee, San Jose, CA (US); Akira Goda, Tokyo (JP); Yoshihiko Kamata, Yokohama City (JP); Koichi Kawai, Yokohama City (JP)

(21) Appl. No.: 19/238,940

(22) Filed: Jun. 16, 2025

Related U.S. Application Data
(60) Provisional application No. 63/665,454, filed on Jun. 28, 2024.

(51) Int. Cl. G11C 16/34; G11C 16/04; G11C 16/10

(52) U.S. Cl. CPC G11C 16/3459; G11C 16/10; G11C 16/0483

(57) ABSTRACT

A method includes causing, in between applying programming pulses to selectively store data to multiple voltage levels of a plurality of memory cells, a second occurrence of a first analog verify operation to be performed on a first set of memory cells to identify one or more memory cells of a first subset of the first set of memory cells. The first subset of memory cells are those that failed the first analog verify operation and the one or more memory cells twice failed the first analog verify operation. A first occurrence of a second analog verify operation is performed at a second set of memory cells to identify a second subset of the second set of memory cells that failed the second analog verify operation.

### CLAIM OF PRIORITY

The present application claims the benefit under 35 U.S.C. § 119(e) of U.S. Provisional Patent Application No. 63/665,454 filed Jun. 28, 2024, which is incorporated by reference herein.

### TECHNICAL FIELD

Embodiments of the disclosure are generally related to memory sub-systems, and more specifically, relate to program level-based programming with multiple analog program verify operations between programming pulses.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of some embodiments of the disclosure.

FIG. 1A illustrates an example computing system that includes a memory sub-system in accordance with some embodiments.

FIG. 1B is a block diagram of a memory device in communication with a memory sub-system controller of a memory sub-system according to an embodiment.

FIG. 2 is a schematic of portions of an array of memory cells as could be used in a memory of the type described with reference to FIG. 1B according to an embodiment.

FIGS. 3A-3B are graphs of conceptual depictions of threshold voltage distributions of a plurality of memory cells of different memory densities according to at least one embodiment.

FIGS. 4A-4B are schematics of portions of a page buffer circuit as could be used in a memory of the type described with reference to FIGS. 1A-1B according to some embodiments.

FIG. 5 are graphs of diagrammatic illustrations that depict a population of memory cells during a programming operation to program selected memory cells to a target voltage using selective slow program convergence according to at least one embodiment.

FIG. 6 is a graph illustrating nine programming pulses and fourteen program verify operations performed across a population of triple-level memory cells (TLCs) according to an embodiment.

FIG. 7A, FIG. 7B, FIB. 7C are flow diagrams of an example method of program level-based programming with multiple analog program verify operations between programming pulses according to some embodiments.

FIG. 8 is a block diagram of an example computer system in which embodiments of the present disclosure can operate.

### DETAILED DESCRIPTION

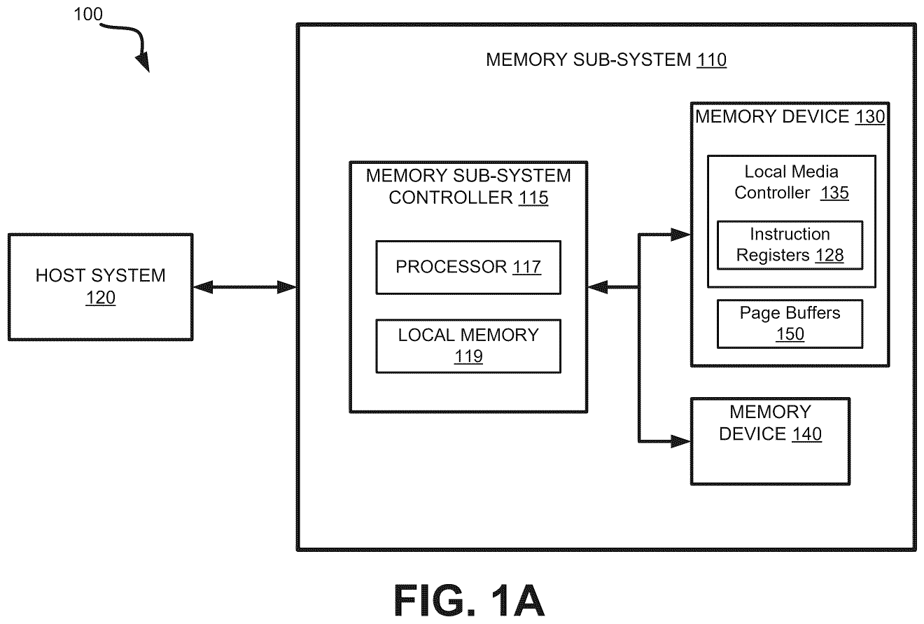

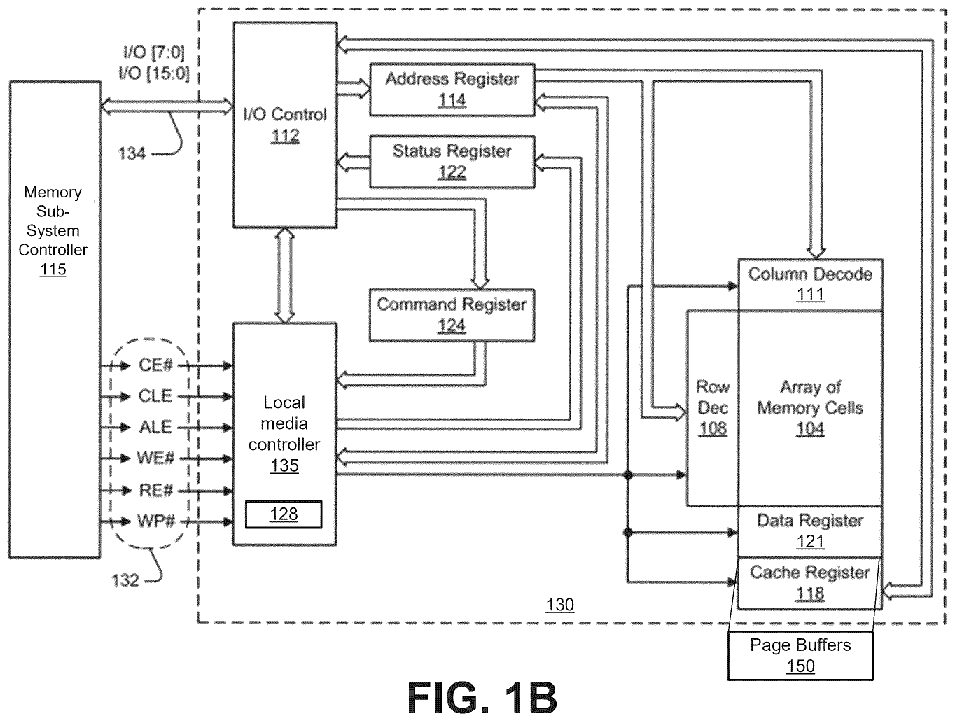

Embodiments of the present disclosure are directed to memory devices employing level-based programming with multiple analog program verify operations between programming pulses. A memory device can be a non-volatile memory device. One example of non-volatile memory devices is a negative-and (NAND) memory device, which is an example of a flash memory device. Other examples of non-volatile memory devices are described below in conjunction with FIG. 1A. These memory devices include memory cells in which to store data. For example, changes in threshold voltage (Vt) of the memory cells, through programming (which is often referred to as writing) of charge storage structures (e.g., floating gates or charge traps) or other physical phenomena (e.g., phase change or polarization), determine the data state (or data value) of each memory cell.

In programming memory, memory cells can generally be programmed as single-level cells (SLC) or multiple-level cells (MLC). Single-level cells can use a single memory cell to represent one digit (e.g., bit) of data. For example, in SLC, a Vt of 2.5V can indicate a programmed memory cell (e.g., representing a logical 0) while a Vt of −0.5V can indicate an erased cell (e.g., representing a logical 1). As an example, the erased state in SLC can be represented by any threshold voltage less than or equal to 0V, while the programmed data state can be represented by any threshold voltage greater than 0V. Multiple-level cells use more than two Vt ranges, where each Vt range indicates a different data state. A margin (e.g., a certain number of volts) such as a dead space can separate adjacent Vt ranges to facilitate differentiating between data states. Multiple-level cells can take advantage of the analog nature of traditional non-volatile memory cells by assigning a bit pattern to a specific Vt range.

In multi-level memory cell programming (e.g., of MLC memory), data values are often programmed using more than one pass, e.g., programming one or more digits in each pass. For example, in four-level MLC (typically referred to simply as MLC), a first digit, e.g., a least significant bit (LSB), which is often referred to as lower page (LP) data, can be programmed to the memory cells in a first pass, thus resulting in two (e.g., first and second) threshold voltage ranges. Subsequently, a second digit, e.g., a most significant bit (MSB), which is often referred to as upper page (UP) data can be programmed to the memory cells in a second pass, typically moving some portion of those memory cells in the first threshold voltage range into a third threshold voltage range, and moving some portion of those memory cells in the second threshold voltage range into a fourth threshold voltage range. Similarly, eight-level MLC (typically referred to as TLC) can represent a bit pattern of three bits, including a first digit, e.g., a least significant bit (LSB) or lower page (LP) data; a second digit, e.g., upper page (UP) data; and a third digit, e.g., a most significant bit (MSB) or extra page (XP) data. In operating TLC, the LP data can be programmed to the memory cells in a first pass, resulting in two threshold voltage ranges, followed by the UP data and the XP data in a second pass, resulting in eight threshold voltage ranges. Similarly, sixteen-level MLC (typically referred to as QLC) can represent a bit pattern of four bits, and 32-level MLC (typically referred to as PLC) can represent a bit pattern of five bits.

Programming in memories is typically accomplished by applying one or more programming pulses, separated by verify pulses, to program each memory cell of a selected group of memory cells to a respective target data state (which might be an interim or final data state). With such a scheme, the programming pulses are applied to access lines, such as those typically referred to as wordlines, for selected memory cells. After each programming pulse, one or more verify voltage levels are typically used to verify the programming of the selected memory cells. Programming typically uses many programming pulses in an incremental step pulse programming (ISPP) scheme, where each programming pulse is a single-level pulse that moves the memory cell threshold voltage by some amount.

The programming pulses might be applied to a selected access line (e.g., wordline) and thus to the control gates of the row of memory cells connected to the selected access line (e.g., having their control gates connected to the selected access line). Typical programming pulses might start at or near a particular program (or gate) step voltage (e.g., 13V, 16V, or the like) and tend to increase in magnitude for each subsequent programming pulse application. While the program potential (e.g., voltage level of the programming pulse) is applied to the selected access line, an enable voltage, such as a reference potential (e.g., 0V), might be applied to the channels (also referred to as bitlines or data lines) of memory cells selected for programming, i.e., those memory cells for which the programming operation is intended to shift their data state to some higher level. This might result in a charge transfer from the channel to the charge storage structures of these selected memory cells. For example, floating gates are typically charged through direct injection or Fowler-Nordheim tunneling of electrons from the channel to the floating gate, resulting in an increased threshold voltage in a programmed state.

An inhibit voltage level (e.g., Vcc) is typically applied to data lines which are selectively connected to a NAND string containing a memory cell that is connected to the selected access line and is not selected for, or is no longer selected for, programming. In addition to data lines selectively connected to memory cells already at their target data state, these unselected data lines might further include data lines that are not addressed by the programming operation. For example, a logical page of data might correspond to memory cells connected to a particular access line and selectively connected to some particular subset of the data lines (e.g., every other data line), such that the remaining subset of data lines would be unselected for the programming operation and thus inhibited.

Between the application of one or more programming pulses, a verify phase of the programming operation is typically performed to check each selected memory cell to determine if the selected memory cell has reached its target data state. If the selected memory cell has reached its target data state, the selected memory cell might be inhibited from further programming if there remain other selected memory cells still requiring additional programming pulses to reach their target data states. Following a verify phase, an additional programming pulse might be applied if there are memory cells that have not completed programming. This process of applying a programming pulse followed by verification (e.g., a programming phase and a verify, or sensing, phase of a programming operation) typically continues until all the selected memory cells have reached their target data states. If a particular number of programming pulses (e.g., maximum number) have been applied, or a particular voltage level of a programming pulse (e.g., maximum voltage level) has been reached, and one or more selected memory cells still have not completed programming, those memory cells might be marked as defective, for example.

The use of different voltage levels on data lines to be enabled for programming might occur in programming schemes known as selective slow programming convergence (SSPC), where memory cells nearer to their respective target data states are programmed more slowly (e.g., partially enabled for programming) compared to memory cells farther from their respective target data states (e.g., fully enabled for programming) while receiving a same voltage level at their respective control gates. SSPC programming schemes can facilitate more narrow distributions of threshold voltages defining each data state over more traditional programming schemes that rely on memory cells being either fully enabled or inhibited from programming. By narrowing the threshold voltage distributions, and thus providing more dead space, or margin, between adjacent threshold voltage distributions, accuracy of determining data states of memory cells might be improved and/or memory density (e.g., number of digits of data per memory cell) might be increased.

Although SSPC programming schemes can provide for tighter threshold voltage distributions over more traditional programming schemes, that benefit typically comes with a cost. In particular, memory cells subject to the programming operation must generally be apportioned to different subsets of memory cells for each programming pulse, e.g., one subset of memory cells to be inhibited from programming, one subset of memory cells to be enabled (e.g., fully enabled) for programming, and one subset of memory cells for each level of partial enablement of programming. Each subset of memory cells might correspond to a respective, mutually exclusive, range of threshold voltages. The threshold voltage for each memory cell subject to the programming operation must generally be determined or estimated in order to apportion it to the proper subset of memory cells. This can add time and/or complexity to the verify phase of the programming operation.

Certain memory devices deploy a process that seeks to facilitate further narrowing of threshold voltage distributions over typical SSPC programming schemes, while mitigating a need to apportion memory cells for each level of partial enablement of programming. These memory devices provide a data line voltage level during a subsequent programming pulse that is inversely related to its corresponding NAND string current level (e.g., I_{string}) during a verify phase of the programming operation (e.g., an immediately prior verify phase of the programming operation). Consider the example of eight NAND strings each having a memory cell selected for programming during a programming operation, and exhibiting I_{string} values of I0, I1, I2, I3, I4, I5, I6, and I7 during a verify phase of the programming operation, where I0<I1<I2<I3<I4<I5<I6<I7. During a subsequent programming pulse, their corresponding data lines might receive voltage levels of V0, V1, V2, V3, V4, V5, V6, and V7, respectively, where V0>V1>V2>V3>V4>V5>V6>V7.

These certain memory devices also capture a retained voltage level of a node of a page buffer circuit following or during a verify phase of the programming operation. During the verify phase of the programming operation, the node might be precharged, and then selectively discharged through a data line responsive to a level of activation of a selected memory cell of a programming operation. As such, a memory cell having a higher threshold voltage, e.g., a lower I_{string} in response to a given control gate voltage level, might be expected to result in a higher retained voltage level at the node than a memory cell having a lower threshold voltage, e.g., a higher I_{string} in response to the given control gate voltage level. The remaining voltage level of the node might subsequently be used as a control voltage of a source-follower to generate a data line (e.g., bitline) voltage level for a subsequent programming operation. In this manner, memory cells closer to their target threshold voltage might be expected to receive a higher data line voltage, e.g., lower level of partial enablement, and memory cells farther from their target threshold voltage might be expected to receive a lower data line voltage, e.g., higher level of partial enablement. Such a verify phase might be referred to as an analog verification (or analog verify operation), as the subsequent data line voltage level is not entirely determined in response to whether a sense transistor is activated or not, but is instead open to data line voltage levels that might be proportional (e.g., inversely proportional) to a level of current flow through its corresponding memory cell.

The process in these certain memory devices facilitates programming a plurality of memory cells to respective ones of N+1 possible data states using N+1 programming pulses. However, the currently implemented process accepts that some memory cells might not reach their desired threshold voltage in such a manner. For example, the bitline (or data line) voltage range is limited to about one volt (V) and has a wide program voltage sigma (PVS), sometimes causing lower tail bits of some voltage distributions, which represent data states, to remain below a program verify voltage after a programming operation and potentially cause read errors. Thus, there is an expectation that error correction schemes might resolve any such errors.

In various embodiments, the present disclosure explains how these lower tail bits of some distributions can be fully programmed, e.g., to be tightened by receiving the minor additional charge needed to pass program verification. For example, even after programming pulses further program memory cells that previously failed in program verification, some memory cells of a data state (e.g., one or more of the L1 memory cells) can be programmed while programming higher data states, e.g., L3 memory cells in this particular example. In this way, according to this example, L1 memory cells that twice failed a first analog program verify operation can complete programming and be less likely to result in read errors.

More specifically, various embodiments described herein seek to mitigate errors caused by memory cells not reaching their intended threshold voltages by further programming such memory cells while using one additional analog verify operation between programming pulses and one additional programming pulse at the end of the multi-level cell programing operation. While some approaches to ISPP programming have included a digital verify operation as well as an analog verify operation in between programming pulses, the present disclosure replaces the digital verify operation with an additional analog verify operation in order to determine a more granular program verify level for memory cells that have been programmed by the past two programming pulses during a multi-cell programming operation.

In various embodiments, for example, control logic of a memory device causes, in between applying programming pulses to selectively store data to multiple voltage levels of a plurality of memory cells, a second occurrence of a first analog verify operation to be performed on a first set of memory cells to identify one or more memory cells of a first subset of the first set of memory cells. In embodiments, the first subset of memory cells failed the first analog verify operation, and the one or more memory cells twice failed the first analog verify operation. In embodiments, the control logic also causes a first occurrence of a second analog verify operation to be performed at a second set of memory cells to identify a second subset of the second set of memory cells that failed the second analog verify operation. As used herein, a memory cell will be deemed the focus of a verification if the control gate voltage level, e.g., the verify voltage level, used during that verification corresponds to the intended data state for that memory cell. Further, at a subsequent programing operation of the first and second set of memory cells, a finalize analog voltage level can be applied to bitlines coupled to the one or more memory cells of the first subset of memory cells while an analog enable voltage level can be applied to bitlines coupled to the second subset of memory cells. The finalize analog voltage level can be higher than the analog enable voltage in order to allow a smaller amount of charge to finalize programming the one or more cells that twice failed the first analog verify operation.

Advantages of the present disclosure include, but are not limited to, improved read window budget (RWB) or read gaps between threshold voltage (Vt) distributions that distinguish data states within memory cells configured as MLC memory. The additional program pulse to clean up any lower tail bits of the final Vt distribution can be hidden under a level n+2 program pulse, thus saving in programming time. While for triple-level cell (TLC) memory, as an example, the present approach employs nine programming pulses (e.g., programming operations) and 14 program verify operations, there is still at least a 40% program time (tPROG) improvement over conventional ISPP. Additional advantages, as would be apparent those skilled in the art of SSPC and ISPP-based programming, will be further discussed hereafter.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such media or memory devices. The memory sub-system 110 can be a storage device, a memory module, or a hybrid of a storage device and memory module.

The memory device 130 can be a non-volatile memory device. One example of non-volatile memory devices is a negative-and (NAND) memory device. A non-volatile memory device is a package of one or more dice. Each die can include one or more planes. Planes can be groups into logic units (LUN). For some types of non-volatile memory devices (e.g., NAND devices), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1,” or combinations of such values.

The memory device 130 can be made up of bits arranged in a two-dimensional or three-dimensional grid, also referred to as a memory array. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface, Open NAND Flash Interface (ONFI) interface, or some other interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130,140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which includes a raw memory device 130 having control logic (e.g., local media controller 135) on the die and a controller (e.g., memory sub-system controller 115) for media management within the same memory device package. An example of a managed memory device is a managed NAND (MNAND) device.

In some embodiments, the memory device 130 includes page buffers 150, which can be used to program data to the memory cells of the memory device 130 and to read the data out of the memory cells. Control logic of the local media controller 135 can be configured to coordinate the timing and manner of applying one of three different voltage biases for selective slow program convergence voltage programming, as will be explained in detail. These three different bias voltages can be associated with, for example, program verify pass voltage (e.g., inhibit bias voltage), a selective slow program convergence voltage (e.g., PPV or a partially enabled voltage), and a program verify fail voltage (e.g., ground or Vss meant for fully enabling programming).

In at least some embodiments, the local media controller 135 (e.g., control logic) includes instruction registers 128, which represent computer-usable memory for storing computer-readable instructions. For some embodiments, the instruction registers 128 represent firmware. Alternatively, the instruction registers 128 represent a grouping of memory cells, e.g., reserved block(s) of memory cells, of an array of memory cells 104 (see FIG. 1A).

FIG. 1B is a simplified block diagram of a first apparatus, in the form of a memory device 130, in communication with a second apparatus, in the form of a memory sub-system controller 115 of a memory sub-system (e.g., the memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device.

The memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line can be associated with more than one logical row of memory cells and a single data line can be associated with more than one logical column. Memory cells (not shown in FIG. 1B) of at least a portion of the array of memory cells 104 are capable of being programmed to one of at least two target data states.

Row decode circuitry 108 and column decode circuitry 111 are provided to decode address signals. Address signals are received and decoded to access the array of memory cells 104. The memory device 130 also includes input/output (I/O) control circuitry 112 to manage input of commands, addresses and data to the memory device 130 as well as output of data and status information from the memory device 130. An address register 114 is in communication with the I/O control circuitry 112 and row decode circuitry 108 and column decode circuitry 111 to latch the address signals prior to decoding. A command register 124 is in communication with the I/O control circuitry 112 and the local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations, and/or erase operations) on the array of memory cells 104. The local media controller 135 is in communication with row decode circuitry 108 and column decode circuitry 111 to control the row decode circuitry 108 and column decode circuitry 111 in response to the addresses.

The local media controller 135 is also in communication with a cache register 118 and a data register 121. The cache register 118 latches data, either incoming or outgoing, as directed by the local media controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in the cache register 118 from the I/O control circuitry 112. During a read operation, data can be passed from the cache register 118 to the I/O control circuitry 112 for output to the memory sub-system controller 115; then new data can be passed from the data register 121 to the cache register 118. The cache register 118 and/or the data register 121 can form (e.g., can form at least a portion of) the page buffers 150 of the memory device 130. The page buffers 150 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to the memory sub-system controller 115.

The memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various embodiments.

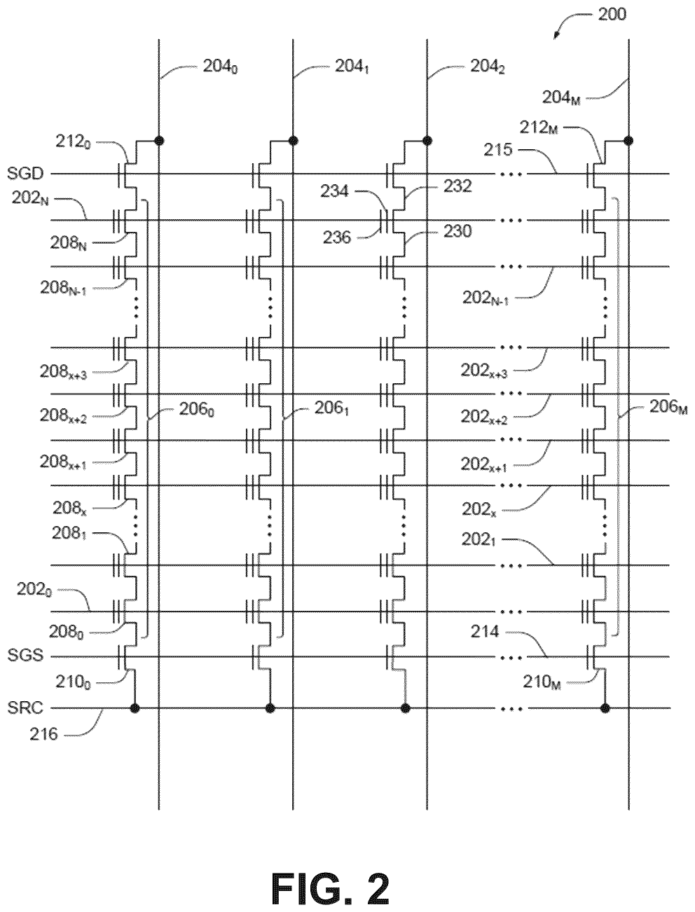

FIG. 2 is a schematic of portions of an array of memory cells 200, such as a NAND memory array, as could be used in a memory of the type described with reference to FIG. 1B according to an embodiment, e.g., as a portion of the array of memory cells 104. Memory array 200 includes access lines, such as wordlines 2020 to 202N, and data lines, such as bitlines 2040 to 204M. The wordlines 202 can be connected to global access lines (e.g., global wordlines), not shown in FIG. 2, in a many-to-one relationship. For some embodiments, memory array 200 can be formed over a semiconductor that, for example, can be conductively doped to have a conductivity type, such as a p-type conductivity, e.g., to form a p-well, or an n-type conductivity, e.g., to form an n-well. The bitlines 2040 can include a plurality of bitlines, each selectively coupled to a respective memory cell of the plurality of memory cells of the array of memory cells 104 and operatively coupled to the control logic of the local media controller 135.

Memory array 200 can be arranged in rows (each corresponding to a wordline 202) and columns (each corresponding to a bitline 204). Each column can include a string of series-connected memory cells (e.g., non-volatile memory cells), such as one of NAND strings 2060 to 206M. Each NAND string 206 can be connected (e.g., selectively connected) to a common source (SRC) 216 and can include memory cells 2080 to 208N. The memory cells 208 can represent non-volatile memory cells for storage of data. The memory cells 208 of each NAND string 206 can be connected in series between a select gate 210 (e.g., a field-effect transistor), such as one of the select gates 2100 to 210M (e.g., that can be source select transistors, commonly referred to as select gate source), and a select gate 212 (e.g., a field-effect transistor), such as one of the select gates 2120 to 212M (e.g., that can be drain select transistors, commonly referred to as select gate drain). Select gates 2100 to 210M can be commonly connected to a select line 214, such as a source select line (SGS), and select gates 2120 to 212M can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 2080 of the corresponding NAND string 206. For example, the drain of select gate 2100 can be connected to memory cell 2080 of the corresponding NAND string 2060. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 2120 can be connected to the bitline 2040 for the corresponding NAND string 2060. The source of each select gate 212 can be connected to a memory cell 208N of the corresponding NAND string 206. For example, the source of select gate 2120 can be connected to memory cell 208N of the corresponding NAND string 2060. Therefore, each select gate 212 can be configured to selectively connect a corresponding NAND string 206 to the corresponding bitline 204. A control gate of each select gate 212 can be connected to select line 215.

The memory array 200 in FIG. 2 can be a quasi-two-dimensional memory array and can have a generally planar structure, e.g., where the common source 216, NAND strings 206 and bitlines 204 extend in substantially parallel planes. Alternatively, the memory array 200 in FIG. 2 can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202N and selectively connected to even bitlines 204 (e.g., bitlines 2040, 2042, 2044, etc.) can be one physical page of the memory cells 208 (e.g., even memory cells) while memory cells 208 commonly connected to wordline 202N and selectively connected to odd bitlines 204 (e.g., bitlines 2041, 2043, 2045, etc.) can be another physical page of the memory cells 208 (e.g., odd memory cells).

Although bitlines 2043-2045 are not explicitly depicted in FIG. 2, it is apparent from the figure that the bitlines 204 of the array of memory cells 200 can be numbered consecutively from bitline 2040 to bitline 204M. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 2020-202N (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

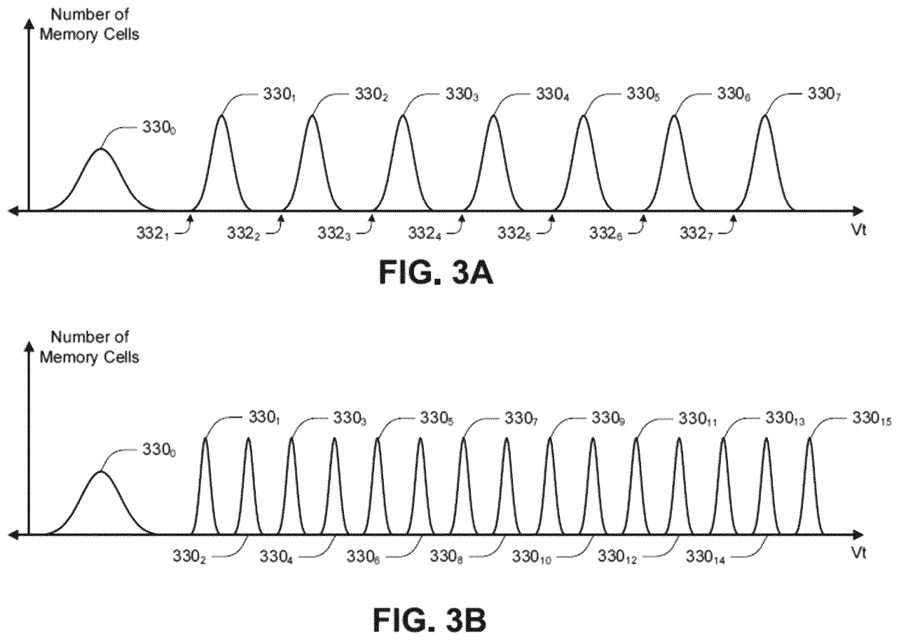

FIGS. 3A-3B are graphs of conceptual depictions of threshold voltage distributions of a plurality of memory cells of different memory densities according to at least one embodiment. FIG. 3A illustrates an example of threshold voltage distributions and their threshold voltage ranges for a population of a eight-level memory cells, often referred to as TLC memory cells. For example, such a memory cell might be programmed to a threshold voltage (Vt) that falls within one of eight different threshold voltage distributions 330₀-330₇, each being used to represent a data state corresponding to a bit pattern of three bits. The threshold voltage distribution 330₀ typically has a greater width than the remaining threshold voltage distributions 330₁-330₇ as memory cells are generally all placed in the data state corresponding to the threshold voltage distribution 330₀, then subsets of those memory cells are subsequently programmed to have threshold voltages in one of the threshold voltage distributions 330₁-330₇. As programming operations are generally more incrementally controlled than erase operations, these threshold voltage distributions 330₁-330₇ may tend to have tighter distributions.

The threshold voltage distributions 330₀, 330₁, 330₂, 330₃, 330₄, 330₅, 330₆, and 330₇ might each represent a respective data state, e.g., L0, L1, L2, L3, L4, L5, L6, and L7, respectively. The eight data states L0-L7 might be thought of as an initial data state L0 and seven remaining data states L1-L7. As an example, if the threshold voltage of a memory cell is within the first of the eight threshold voltage distributions 330₀, the memory cell in this case may be storing a data state L0 having a data value of logical ‘111’ and is typically referred to as the erased or initial data state of the memory cell. If the threshold voltage is within the second of the eight threshold voltage distributions 330₁, the memory cell in this case may be storing a data state L1 having a data value of logical ‘011’. If the threshold voltage is within the third of the eight threshold voltage distributions 330₂, the memory cell in this case may be storing a data state L2 having a data value of logical ‘001’, and so on. Table 1 provides one possible correspondence between the data states and their corresponding logical data values. Other assignments of data states to logical data values are known. Memory cells remaining in the lowest data state (e.g., the initial data state or L0 data state), as used herein, will be deemed to be programmed to the lowest data state. The information of Table 1 might be contained within the trim register 127, for example.

TABLE 1

| Data State | Logical Data Value |
|---|---|
| L0 | 111 |
| L1 | 011 |
| L2 | 001 |
| L3 | 101 |
| L4 | 100 |
| L5 | 000 |
| L6 | 010 |
| L7 | 110 |

In programming the memory cells represented by the threshold voltage distributions 330₁-330₇, one or more programming pulses might be applied to control gates of the memory cells following by a verification. For example, in programming memory cells of the threshold voltage distribution 330₁, a verify voltage level 332₁ might be applied to the control gates of those memory cells. If a memory cell having the data state L1 as its intended data state is deactivated in response to the verify voltage level 332₁, it might be deemed to have passed verification, such that it might be inhibited from programming for subsequent programming pulses. If that memory cell is activated in response to the verify voltage level 332₁, it might be deemed to have failed verification, such that it might be enabled, e.g., either partially or fully enabled, for programming for a subsequent programming pulse. Each threshold voltage distribution 330₂-330₇ might have a corresponding verify voltage level 332₂-332₇, respectively, and might follow a similar logic process to determine whether to inhibit or enable their corresponding memory cells for subsequent programming pulses as discussed with reference to the threshold voltage distribution 330₁.

FIG. 3B is another conceptual depiction of threshold voltage distributions of a plurality of memory cells of a second memory density, e.g., four digits of data per memory cell. FIG. 3B illustrates an example of threshold voltage distributions and their distributions for a population of a sixteen-level memory cells, often referred to as QLC memory cells. For example, such a memory cell might be programmed to a threshold voltage (Vt) that falls within one of sixteen different threshold voltage distributions 330₀-330₁₅, each being used to represent a data state corresponding to a bit pattern of four bits. The threshold voltage distribution 330₀ typically has a greater width than the remaining threshold voltage distributions 330₁-330₁₅ as memory cells are generally all placed in the data state corresponding to the threshold voltage distribution 330₀, then subsets of those memory cells are subsequently programmed to have threshold voltages in one of the threshold voltage distributions 330₁-330₁₅. As programming operations are generally more incrementally controlled than erase operations, these threshold voltage distributions 330₁-330₁₅ may tend to have tighter distributions.

The threshold voltage distributions 330₀, 330₁, 330₂, 330₃, 330₄, 330₅, 330₆, 330₇, 330₈, 330₉, 330₁₀, 330₁₁, 330₁₂, 330₁₃, 330₁₄ and 330₁₅ might each represent a respective data state, e.g., L0, L1, L2, L3, L4, L5, L6, L7, L8, L9, L10, L11, L12, L13, L14 and L15, respectively. The sixteen data states L0-L15 might be thought of as an initial data state L0 and fifteen remaining data states L1-L15. As an example, if the threshold voltage of a memory cell is within the first of the sixteen threshold voltage distributions 330₀, the memory cell in this case may be storing a data state L0 having a data value of logical ‘1111’ and is typically referred to as the erased or initial data state of the memory cell. If the threshold voltage is within the second of the sixteen threshold voltage distributions 330₁, the memory cell in this case may be storing a data state L1 having a data value of logical ‘0111’. If the threshold voltage is within the third of the sixteen threshold voltage distributions 330₂, the memory cell in this case may be storing a data state L2 having a data value of logical ‘0011’, and so on. Table 2 provides one possible correspondence between the data states and their corresponding logical data values. Other assignments of data states to logical data values are known. Memory cells remaining in the lowest data state (e.g., the initial data state or L0 data state), as used herein, will be deemed to be programmed to the lowest data state. The information of Table 2 might be contained within the trim register 127, for example.

TABLE 2

| Data State | Logical Data Value |
|---|---|
| L0 | 1111 |
| L1 | 0111 |
| L2 | 0011 |
| L3 | 1011 |
| L4 | 1001 |
| L5 | 0001 |
| L6 | 0101 |
| L7 | 1101 |
| L8 | 1100 |
| L9 | 0100 |
| L10 | 0000 |
| L11 | 1000 |
| L12 | 1010 |
| L13 | 0010 |
| L14 | 0110 |
| L15 | 1110 |

Although not depicted in FIG. 3B, each threshold voltage distribution 330₁-330₁₅ might have a corresponding verify voltage level 332₁-332₁₅, respectively, and might follow a similar logic process to determine whether to inhibit or enable their corresponding memory cells for subsequent programming pulses as discussed with reference to threshold voltage distribution 330₂-330₇ of FIG. 3A.

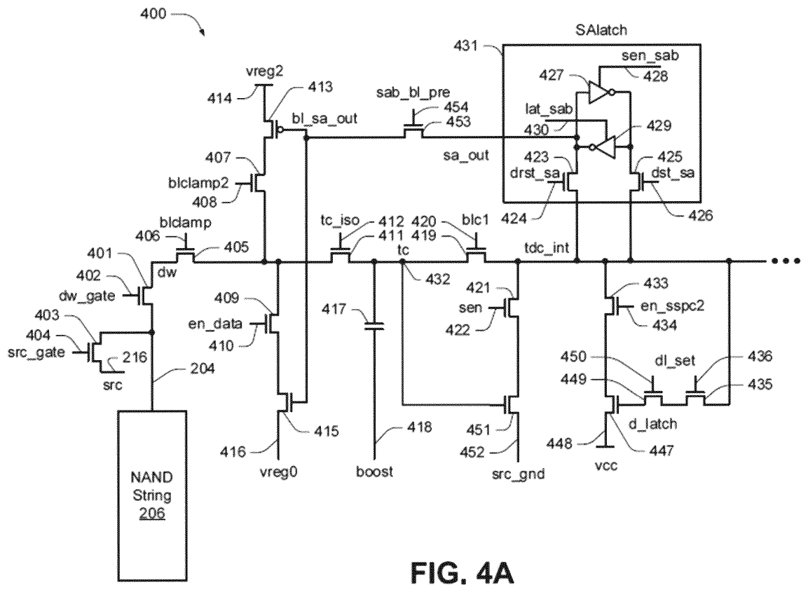

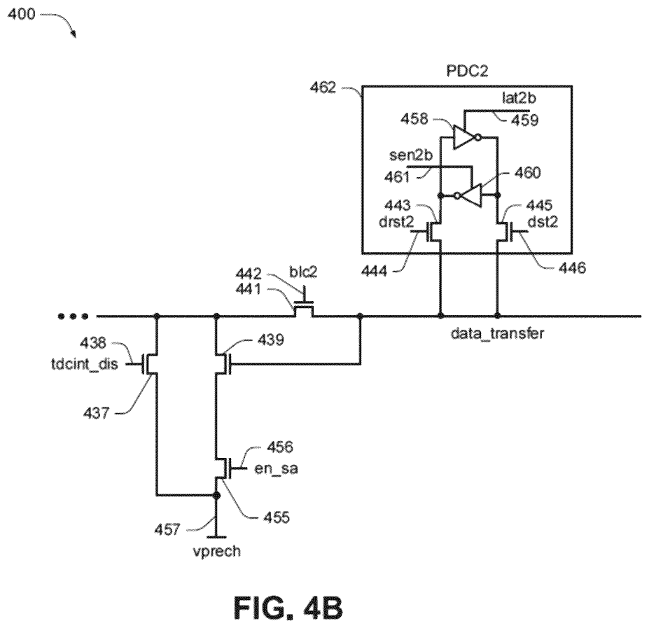

FIGS. 4A-4B are schematics of portions of a page buffer circuit 400 as could be used in a memory of the type described with reference to FIGS. 1A-1B according to some embodiments. Page buffer circuit 400 might be connected (e.g., selectively connected) to a NAND string 206 through a data line 204. Page buffer circuit 400 might include transistors 401, 403, 405, 407, 409, 411, 413, 415, 419, 421, 433, 435, 437, 439, 441, 447, 449, 451, 453, and 455. The page buffer circuit 400 might further include a sense capacitor 417, a sense amplifier latch 431, and a data latch 462. Transistor 413 might be a p-type field-effect transistor (pFET), while transistors 401, 403, 405, 407, 409, 411, 415, 419, 421, 433, 435, 437, 439, 441, 447, 449, 451, 453, and 455 might be n-type field-effect transistors (nFETs). Sense amplifier latch 431 might include inverters 427 and 429 and transistors 423 and 425 (e.g., nFETs). Data latch (e.g., PDC2) 462 might include inverters 458 and 460 and transistors 443 and 445 (e.g., nFETs).

The data line 204 might be connected to a first source/drain of transistor 401 and a first source/drain of transistor 403. The control gate of transistor 403 might be connected to a src_gate control signal node 404. The second source/drain of transistor 403 might be connected to the common source 216. The control gate of transistor 401 might be connected to a dw_gate control signal node 402. The second source/drain of transistor 401 might be connected to a first source/drain of transistor 405.

The control gate of transistor 405 might be connected to a blclamp control signal node 406. The second source/drain of transistor 405 might be connected to a first source/drain of transistor 407, a first source/drain of transistor 409, and a first source/drain of transistor 411. The control gate of transistor 407 might be connected to a blclamp2 control signal node 408. The second source/drain of transistor 407 might be connected to a first source/drain of transistor 413. The control gate of transistor 413 might be connected to a first source/drain of transistor 453 and the control gate of transistor 415. The control gate of transistor 453 might be connected to a sab_bl_pre control signal node 454. The second source/drain of transistor 453 might be connected to the input of inverter 427, the output of inverter 429, and a first source/drain of transistor 423. The second source/drain of transistor 413 might be connected to a voltage node (e.g., vreg2) 414. The control gate of transistor 409 might be connected to an en_data control signal node 410. The second source/drain of transistor 409 might be connected to a first source/drain of transistor 415. The second source/drain of transistor 415 might be connected to a voltage node (e.g., vreg0) 416.

The control gate of transistor 411 might be connected to a the_iso control signal node 412. The second source/drain of transistor 411 might be connected to one side (e.g., a first electrode) of sense capacitor 417, a first source/drain of transistor 419, and the control gate of transistor 451 through a tc signal node 432. The other side (e.g., a second electrode) of sense capacitor 417 might be connected to a sense capacitor bias node (e.g., boost node) 418. The control gate of transistor 419 might be connected to a blc1 control signal node 420. The second source/drain of transistor 419 might be connected to a first source/drain of transistor 421, the second source/drain of transistor 423, a first source/drain of transistor 425, a first source/drain of transistor 433, a first source/drain of transistor 435, a first source/drain of transistor 437, a first source/drain of transistor 439, and a first source/drain of transistor 441.

The control gate of transistor 433 might be connected to a en_sspc2 control signal node 434. The second source/drain of transistor 433 might be connected to a first source/drain of transistor 447. The second source/drain of transistor 447 might be connected to a voltage node (e.g., vcc) 448. The control gate of transistor 435 might be connected to a dl_set control signal node 436. The second source/drain of transistor 435 might be connected to a first source/drain of transistor 449. The control gate of transistor 449 might be connected to a d_latch control signal node 450. The second source/drain of transistor 449 might be connected to the control gate of transistor 447.

The control gate of transistor 421 might be connected to a sen control signal node 422. The second source/drain of transistor 421 might be connected to a first source/drain of transistor 451. The second source/drain of transistor 451 might be connected to a source bias node (e.g., src_gnd) 452. The transistor 451 might be referred to as a sense transistor.

The control gate of transistor 423 of sense amplifier latch 431 might be connected to a drst_sa control signal node 424. The control gate of transistor 425 might be connected to a dst_sa control signal node 426. The second source/drain of transistor 425 might be connected to the output of inverter 427 and to the input of inverter 429. A control input of inverter 427 might be connected to a sen_sab control signal node 428. A control input of inverter 429 might be connected to a lat_sab control signal node 430.

The control gate of transistor 437 might be connected to a tccint_dis control signal node 438. The second source/drain of transistor 437 might be connected to a first source/drain of transistor 455 and to a voltage node (e.g., vprech) 457. The control gate of transistor 439 might be connected to the second source/drain of transistor 441, a first source/drain of transistor 443, and a first source/drain of transistor 445. The control gate of transistor 441 might be connected to a blc2 control signal node 442. The control gate of transistor 455 might be connected to a en_sa control signal node 456. The second source/drain of transistor 455 might be connected to the second source/drain of transistor 439.

The control gate of transistor 443 of data latch 462 might be connected to a drst2 control signal node 444. The control gate of transistor 445 might be connected to a dst2 control signal node 446. The second source/drain of transistor 443 might be connected to the output of inverter 460 and to the input of inverter 458. The second source/drain of transistor 445 might be connected to the output of inverter 458 and to the input of inverter 460. A control input of inverter 460 might be connected to a sen2b control signal node 461. A control input of inverter 458 might be connected to a lat2b control signal node 459.

Control logic (e.g., of the local media controller 135 of FIGS. 1A-1B) might be connected to the src_gate control signal node 404, the dw_gate control signal node 402, the blclamp control signal node 406, the blclamp2 control signal node 408, the en_data control signal node 410, the tc_iso control signal node 412, the BLC1 control signal node 420, the sen control signal node 422, the sab_bl_pre control signal node 454, the en_sspc2 control signal node 434, the dl_set control signal node 436, the d_latch control signal node 450, the tdcint_dis control signal node 438, the en_sa control signal node 456, the lat_sab control signal node 430, the sen_sab control signal node 428, the drst_sa control signal node 424, the dst_sa control signal node 426, the sen2b control signal node 461, thae lat2b control signal node 459, the drst2 control signal node 444, and the dst2 control signal node 446 to control the operation of page buffer circuit 400.

Page buffer circuit 400 might be used to sense the data state of the selected memory cell of the NAND string 206 and latch the sensed data state in sense amplifier latch 431 during a read operation or a verify phase of a programming operation. Page buffer circuit 400 might also be used to program a target data state to the selected memory cell based on a state of the sense amplifier latch 431 or a state of one or more data latches. Additional data latches (not shown in FIGS. 4A-4B) might be connected in parallel with, and have a similar (e.g., same) structure as, the data latch 462.

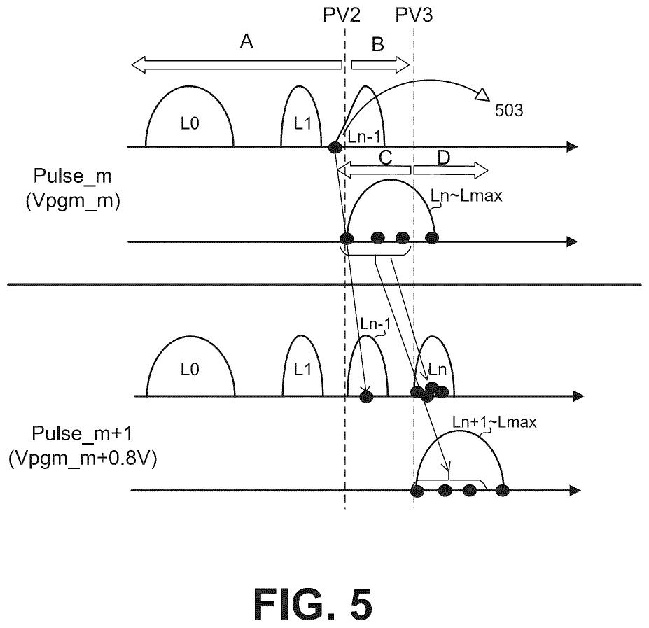

FIG. 5 are graphs of diagrammatic illustrations that depict a population of memory cells during a programming operation to program selected memory cells to a target voltage using selective slow program convergence according to at least one embodiment. In various embodiments, the population of cells begin at an initial data state, L0, as was previously discussed with reference to threshold voltage distribution 330₀ (scc FIGS. 3A-3B). As the population of memory cells is further programmed, each subsequent program verify voltage level is checked in a program verify operation (also referred to as program verification herein) before a subset of memory cells associated with the next state (e.g., currently being programmed) are inhibited from programming. So, for example, as illustrated in FIG. 5, the L1 data state has been fully programmed and data state Ln−1 is being programmed by pulse_m in the upper graphic. Typically, therefore, the memory cells in the Vt range indicated by A would be inhibited while the memory cells in the Vt range indicated by B would be further programmed to generate data state Ln−1, for example. As can be seen, however, a subset of memory cells 503 (or bits) have been left behind in a longer tail of data state Ln−1 than desired. If the subset of memory cells 503 were left at this lower Vt level, errors would likely occur in distinguishing between the L1 and Ln−1 data states.

According to disclosed embodiments, during a subsequent programming pulse (pulse_m+1), the bitline voltage for the subset of memory cells 503 may be shifted to higher bitline voltage, e.g., to a finalize analog voltage level that enables the subset of memory cells 503 to be finished off so that they pass a second analog verify operation. This final programming of the subset of memory cells 503 can occur at the same time as programming the memory cells associated with the Ln−1 data state that also further programs memory cells for the Ln and Ln+1 to Lmax data states. Thus, as can be seen in the bottom graphic, the Ln−1 data state can now pass the program verify operation at a PV2 voltage level while the Ln data state is being verified at a PV3 voltage level. Thus, in embodiments, depending on a target voltage for a Vt level of a particular subset of memory cells, and depending on how many times one or more memory cells have failed a program verify operation, a different bitline voltage can be applied to selectively slow down some programming, causing programming memory cells at different rates depending on how close the Vt levels are to the program verify (PV) voltage level for those particular memory cells.

TABLE 3

| | | Vbl@pulse_m + | Vt shift |
|---|---|---|---|
| Vt Region | Status after Pulse_m | 1 (in V) | @pulse_m + 1 |
| A | Ln − 2 and below | Inhibit | None |
| A | Ln − 1 failed | Finalize Analog | 0~0.3 V |
| B | Ln − 1 passed | Inhibit | None |
| C | Ln failed | Analog Enable | 0~0.3 V |
| D | Ln passed | Inhibit | None |
| C&D | Ln + 1 & above | Digital Low | 0.8 V |

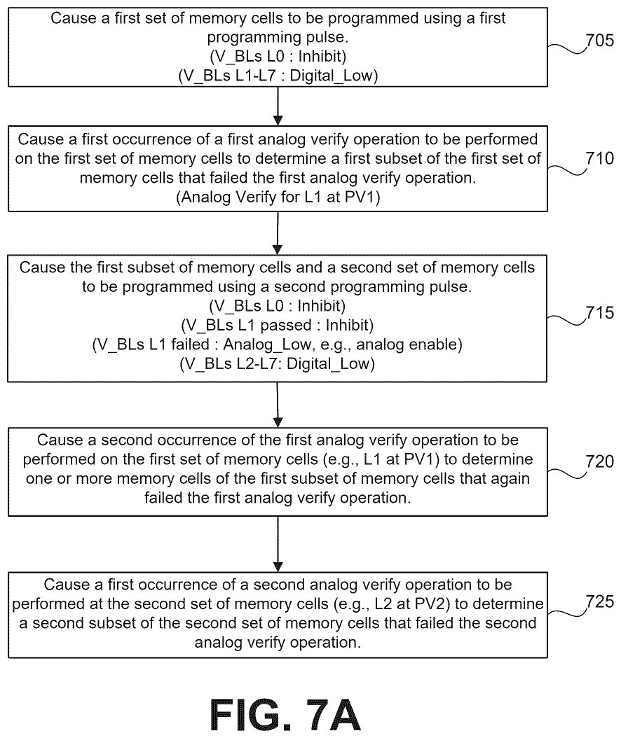

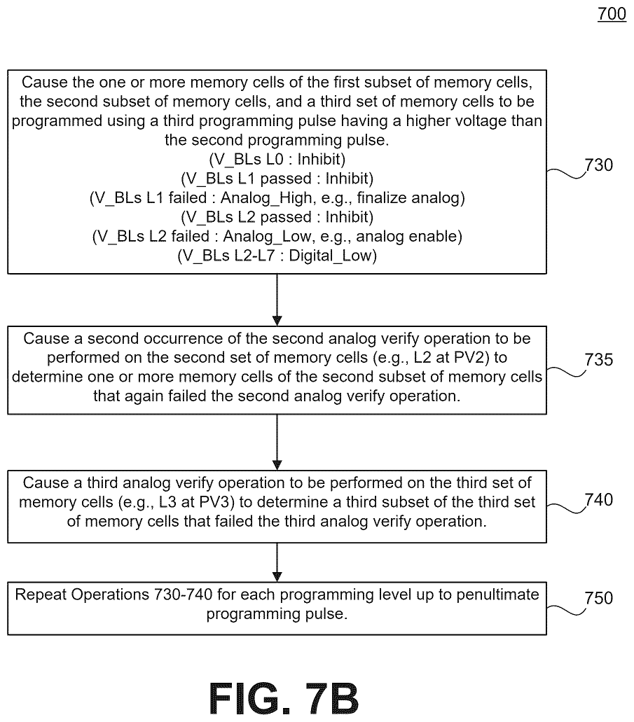

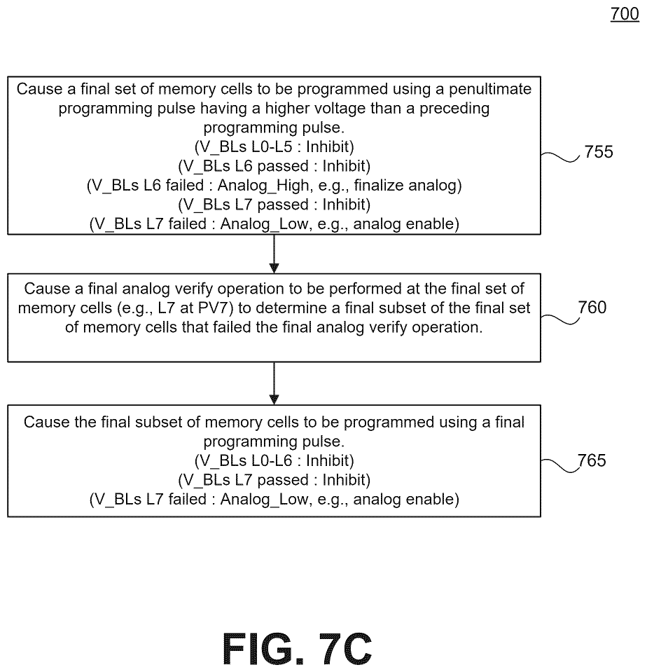

Table 3 is an example of certain subsets of memory cells after pulse_m, with information by columns including: 1) the Vt region of the memory cells; 2) a status of the memory cells; 3) the bitline voltage level to be used for programming by the pulse_m+1 programming pulse; and 4) the Vt shift after the pulse_m+1 programing pulse has been applied. Depending on application and memory device technology, the bitline voltage levels (Vbl) at pulse_m+1 can vary. Just for a sense of relative values and ranges of these bitline voltage levels, in some embodiments, the inhibit voltage is somewhere around 2.0-2.4V, the finalize analog voltage is between 0.5-1.5V and generally expected to be higher than the analog enable voltage, the analog enable voltage is between 0-1.0V, and the digital low voltage is zero (e.g., 0V or approximately 0V). Also, the programming step or gate step voltage increase between pulse_m and pulse_m+1 is illustrated as 0.8V, but this value can also be expected to vary in differing embodiments or memory devices. These different voltage levels will be also be referenced hereinafter with reference to FIGS. 7A-7C, for example.

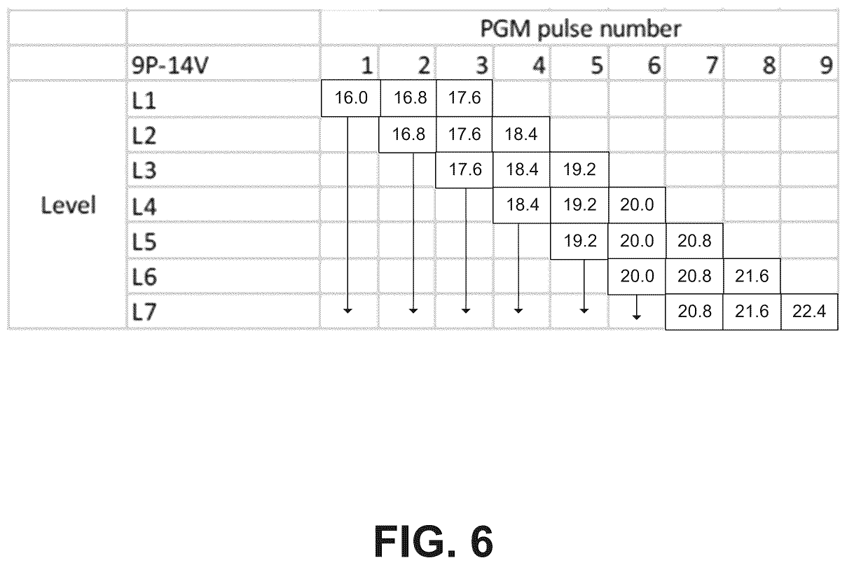

FIG. 6 is a graph illustrating nine programming pulses and fourteen program verify operations performed across a population of triple-level memory cells (TLCs) according to an embodiment, only for purposes of explanation. In this graph, (in which L0 is not illustrated) each data state of the seven data states (L1-L7) of TLC memory can be programmed over a combination of three programming pulses according to at least one embodiment. As each programming pulse is applied to wordlines of the TLC memory cells, the population of memory cells associated with all of the data states are incrementally programmed according to SSPC-based programming (illustrated with the arrows drawn through additional SLC data state levels). Of the three programming pulses, the first two applied to memory cells of each respective data state also involve a program verify operation. The first programming pulse can be followed a single analog program verify operation while each subsequent programming pulse can be followed by two analog program verify operations, one for two prior programming levels (e.g., that clean up any remaining subset of memory cells 503 similar as discussed with reference to FIG. 5) and the other for the immediate previous programming level (see FIGS. 7A-7C for more detail).

In embodiments, each subsequent programming pulse may increase by a gate step voltage (e.g., illustrated as 0.8V but which could be different, like 0.6V, 0.7V, 0.9V or the like) to incrementally increase the programmed Vt levels for each subsequent data state. Thus, for example, programming pulse #1 can be applied using fully enabled programming of all data state levels (L1-L7). Further, programming pulse #2 can be applied using SSPC-based programming to L1 memory cells that failed an L1 program verify operation and be applied using fully enabled programming for the rest of the data state levels (L2-L7). Further, programming pulse #3 can be applied to one or more of the L1 memory cells that still failed the program verify at the L1 program verify voltage, to a subset of L2 memory cells that failed a L2 program verify operation (e.g., using SSPC-based programming), and to the L3 memory cells (in addition to L4-L7 memory cells) using fully enabled programming. Similarly, programming pulse #4 can be applied to one or more of the L2 memory cells that still failed the program verify at the L2 program verify voltage, to a subset of L3 memory cells that failed a L3 program verify operation (e.g., using SSPC-based programming), and to the L4 memory cells (in addition to L5-L7 memory cells) using fully enabled programming.

In embodiments, this sort of programming pattern continues with varying programming pulse voltage levels depending on how close to being fully programmed the respective data state is until there are fewer than three data states left to program. Thus, programming pulse #8 can be applied to just L6 memory cells that still failed the L6 program verify operation and L7 memory cells (using SSPC-based programming). Further, programming pulse #9 can be applied to just L7 memory cells that still failed the L7 program verify operation. For a more specific description of the role of each program verify operation, please see FIGS. 7A-7C.

FIG. 7A, FIG. 7B, FIB. 7C are flow diagrams of an example method 700 of program level-based programming with multiple analog program verify operations between programming pulses according to some embodiments. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 700 is performed by the local media controller 135 (or control logic) of FIGS. 1A-1B that includes instructions registers 128. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

With initial reference to FIG. 7A, assume that multiple sets of memory cells (to be programmed to various data states) are in the initial date state L0, also referred to as an erased state. At operation 705, a first set of memory cells (e.g., L1 memory cells) are programmed. For example, the processing logic causes the first set of memory cells to be programmed using a first programming pulse. During this first programming operation, the bitline voltages for L0 memory cells can be an inhibit voltage and the bitline voltages for the L1-L7 memory cells can be a digital low voltage. Thus, although the first set of memory cells is specifically referenced, it should be understood that other sets of memory cells (for higher data states) are also being programmed as was discussed with reference to FIG. 6.

At operation 710, a first analog verify operation is performed. For example, the processing logic (e.g., control logic of the local media controller 135) causes a first occurrence of a first analog verify operation to be performed on the first set of memory cells to determine a first subset of the first set of memory cells that failed the first analog verify operation. Thus, this first analog verify operation can be understood as an analog verify for L1 at PV1 (a first program verify voltage).

At operation 715, the second set of memory cells is programmed. For example, the processing logic causes the first subset of memory cells and a second set of memory cells to be programmed using a second programming pulse, where the second set of memory cells are L2 memory cells. In embodiments, the second programming pulse has a higher voltage level than the first programming pulse. In some embodiments, the bitline voltage is the inhibit voltage for L0 memory cells and also for the L1 memory cells that have passed the PV1 program verify operation, is the analog enable voltage for the L1 memory cells that have failed the PV1 program verify operation, and is the digital low voltage for memory cells that for L2-L7 memory cells yet to be programmed. Thus, while programming using the second programming pulse, the operations include causing an analog enable voltage level to be applied to bitlines, of a plurality of bitlines, coupled to the first subset of memory cells.

At operation 720, the first analog verify operation is performed again. For example, the processing logic causes a second occurrence of the first analog verify operation to be performed on the first set of memory cells (e.g., for L1 and PV1) to determine one or more memory cells of the first subset of memory cells that again failed the first analog verify operation.

At operation 725, a second program verify operation is performed. For example, the processing logic causes a first occurrence of a second analog verify operation to be performed on the second set of memory cells (e.g., L2 at PV2) to determine a second subset of the second set of memory cells that failed the second analog verify operation.

With additional reference to FIG. 7B, at operation 730, a third set of memory cells is programmed. For example, the processing logic causes the one or more memory cells of the first subset of memory cells, the second subset of memory cells, and a third set of memory cells to be programmed using a third programming pulse having a higher voltage than the second programming pulse. In some embodiments, the bitline voltage is the inhibit voltage for the L0 memory cells, for the L1 memory cells that passed the first program verify operation, and for the L2 memory cells that passed the second program verify operation. Further, in embodiments, the bitline voltage is the digital low voltage for memory cells coupled to the L2-L7 memory cells. Further, also at operation 730, the processing logic causes a finalize analog voltage level to be applied to bitlines, of a plurality of bitlines, coupled to the one or more memory cells of the first subset of memory cells and causes an analog enable voltage level to be applied to bitlines, of the plurality of bitlines, coupled to the second subset of memory cells.

At operation 735, a second analog verify operation is performed. For example, the processing logic causes a second occurrence of the second analog verify operation to be performed on the second set of memory cells (e.g., L2 at PV2) to determine one or more memory cells of the second subset of memory cells that again failed the second analog verify operation.

At operation 740, a third analog verify operation is performed. For example, the processing logic causes a third analog verify operation to be performed on the third set of memory cells (e.g., L3 at PV3) to determine a third subset of the third set of memory cells that failed the third analog verify operation.

At operation 750, the processing logic causes operations 730, 735, and 740 to be repeated for each programming level (e.g., data state level) up to a penultimate programming pulse to be applied.

With additional reference to FIG. 7C, at operation 755, a final set of memory cells is programmed. For example, the processing logic causes a final set of memory cells to be programmed using a penultimate programming pulse having a higher voltage than a preceding programming pulse. In some embodiments, the bitline voltage is the inhibit voltage for the L0-L5 memory cells that are fully programmed, for the L6 memory cells that have passed the PV6 analog verify operation, and for the L7 memory cells that have passed the PV7 analog verify operation. Further, also at operation 755, the processing logic causes a finalize analog voltage level to be applied to bitlines, of a plurality of bitlines, coupled to the one or more memory cells of a sixth subset of memory cells (that twice failed the PV6 analog verify operation) and causes an analog enable voltage level to be applied to bitlines, of the plurality of bitlines, coupled to a seventh subset of memory cells that failed the PV7 analog verify operation.

At operation 760, a final analog verify operation is performed. For example, the processing logic causes a final analog verify operation to be performed at the final set of memory cells (e.g., L7 at PV7) to determine a final subset of the final set of memory cells that failed the final analog verify operation.

At operation 765, a final programming pulse is applied. For example, the processing logic causes the final subset of memory cells to be programmed using a final programming pulse. In embodiment, the first programming pulse through the final programming pulse are numbered one greater than a number of multi-level data states that were programmed at the plurality of memory cells, e.g., L0-L7. In embodiments, the bitline voltage is the inhibit voltage for L0-L6 memory cells and for L7 memory cells that passed the final analog verify operation. In embodiments, also at operation 765, the processing logic causes, while programming using the final programming pulse, an analog enable voltage level to be applied to bitlines coupled to the final subset of memory cells.

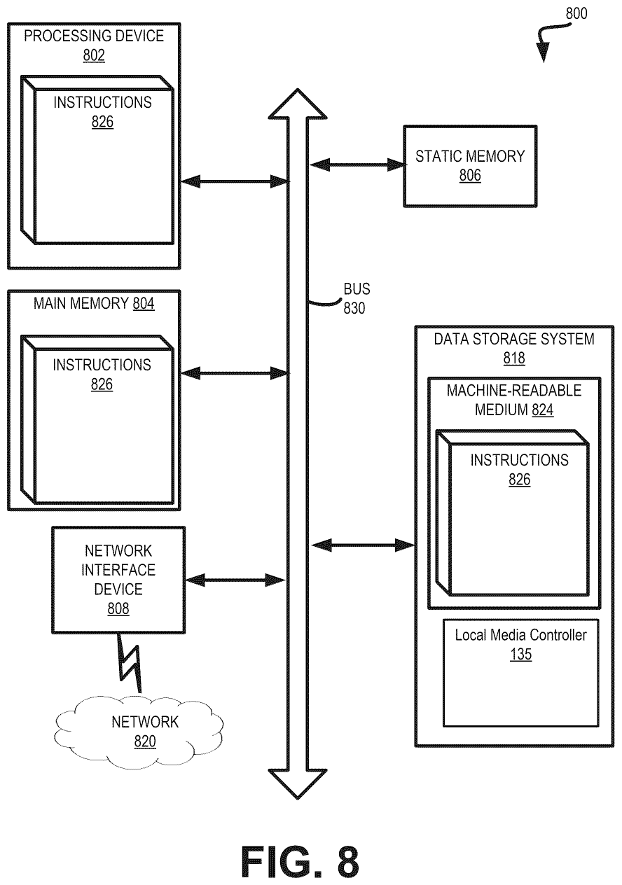

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the local media controller 135 of FIG. 1A), also referred to as control logic herein. In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or Rambus DRAM (RDRAM), etc.), a static memory 810 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 828 for performing the operations and steps discussed herein. The computer system 800 can further include a network interface device 812 to communicate over the network 820.

The data storage system 818 can include a machine-readable storage medium 824 (also known as a computer-readable medium) on which is stored one or more sets of instructions 828 or software embodying any one or more of the methodologies or functions described herein. The data storage system 818 can further include the local media controller 135, which were previously discussed. The instructions 828 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory sub-system 110 of FIG. 1A.

In one embodiment, the instructions 826 include instructions to implement functionality corresponding to a controller (e.g., the memory sub-system controller 115 of FIG. 1A). While the machine-readable storage medium 824 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., non-transitory computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
an array comprising a plurality of memory cells; and
control logic coupled with the array, wherein the control logic, during multi-level memory cell programming, is to perform operations comprising:
causing a first set of memory cells to be programmed using a first programming pulse;
causing a first occurrence of a first analog verify operation to be performed on the first set of memory cells to determine a first subset of the first set of memory cells that failed the first analog verify operation;
causing the first subset of memory cells and a second set of memory cells to be programmed using a second programming pulse;
causing a second occurrence of the first analog verify operation to be performed on the first set of memory cells to determine one or more memory cells of the first subset of memory cells that again failed the first analog verify operation; and
causing a first occurrence of a second analog verify operation to be performed on the second set of memory cells to determine a second subset of the second set of memory cells that failed the second analog verify operation.

2. The memory device of claim 1, wherein the second programming pulse has a higher voltage level than the first programming pulse.

3. The memory device of claim 1, further comprising a plurality of bitlines, each selectively coupled to a respective memory cell of the plurality of memory cells and operatively coupled to the control logic, wherein, while programming using the second programming pulse, the operations further comprise causing an analog enable voltage level to be applied to one or more bitlines, of the plurality of bitlines, associated with the first subset of memory cells.

4. The memory device of claim 1, wherein the operations further comprise causing the one or more memory cells of the first subset of memory cells, the second subset of memory cells, and a third set of memory cells to be programmed using a third programming pulse having a higher voltage than the second programming pulse.

5. The memory device of claim 4, further comprising a plurality of bitlines, each selectively coupled to a respective memory cell of the plurality of memory cells and operatively coupled to the control logic, wherein, while programming using the third programming pulse, the operations further comprise:
causing a finalize analog voltage level to be applied to bitlines, of the plurality of bitlines, coupled to the one or more memory cells of the first subset of memory cells; and
causing an analog enable voltage level to be applied to bitlines, of the plurality of bitlines, coupled to the second subset of memory cells.

6. The memory device of claim 4, wherein the operations further comprise:
causing a second occurrence of the second analog verify operation to be performed on the second set of memory cells to determine one or more memory cells of the second subset of memory cells that again failed the second analog verify operation; and
causing a third analog verify operation to be performed on the third set of memory cells to determine a third subset of the third set of memory cells that failed the third analog verify operation.

7. The memory device of claim 4, wherein the operations further comprise:
causing a final set of memory cells to be programmed using a penultimate programming pulse having a higher voltage than a preceding programming pulse;
causing a final analog verify operation to be performed on the final set of memory cells to determine a final subset of the final set of memory cells that failed the final analog verify operation;
causing the final subset of memory cells to be programmed using a final programming pulse, wherein the first programming pulse through the final programming pulse are numbered one greater than a number of multi-level data states that were programmed in the plurality of memory cells; and
causing, while programming using the final programming pulse, an analog enable voltage level to be applied to bitlines coupled to the final subset of memory cells.

8. A method comprising:
causing, by control logic of a memory device, a first set of memory cells to be programmed using a first programming pulse, wherein the memory device comprises an array of a plurality of memory cells that includes the first set of memory cells;
causing a first occurrence of a first analog verify operation to be performed on the first set of memory cells to determine a first subset of the first set of memory cells that failed the first analog verify operation;
causing the first subset of memory cells and a second set of memory cells to be programmed using a second programming pulse;
causing a second occurrence of the first analog verify operation to be performed on the first set of memory cells to determine one or more memory cells of the first subset of memory cells that again failed the first analog verify operation; and
causing, by the control logic, a first occurrence of a second analog verify operation to be performed on the second set of memory cells to determine a second subset of the second set of memory cells that failed the second analog verify operation.

9. The method of claim 8, wherein the second programming pulse has a higher voltage level than the first programming pulse.

10. The method of claim 8, further comprising, while programming using the second programming pulse, causing an analog enable voltage level to be applied to bitlines, of a plurality of bitlines, coupled to the first subset of memory cells.

11. The method of claim 8, further comprising causing the one or more memory cells of the first subset of memory cells, the second subset of memory cells, and a third set of memory cells to be programmed using a third programming pulse having a higher voltage than the second programming pulse.

12. The method of claim 11, further comprising, while programming using the third programming pulse:
causing a finalize analog voltage level to be applied to bitlines, of a plurality of bitlines, coupled to the one or more memory cells of the first subset of memory cells; and
causing an analog enable voltage level to be applied to bitlines, of the plurality of bitlines, coupled to the second subset of memory cells.

13. The method of claim 11, further comprising:
causing a second occurrence of the second analog verify operation to be performed on the second set of memory cells to determine one or more memory cells of the second subset of memory cells that again failed the second analog verify operation; and
Causing a third analog verify operation to be performed on the third set of memory cells to determine a third subset of the third set of memory cells that failed the third analog verify operation.

14. The method of claim 11, further comprising:
causing a final set of memory cells to be programmed using a penultimate programming pulse having a higher voltage than a preceding programming pulse;
causing a final analog verify operation to be performed at the final set of memory cells to determine a final subset of the final set of memory cells that failed the final analog verify operation;
causing the final subset of memory cells to be programmed using a final programming pulse, wherein the first programming pulse through the final programming pulse are numbered one greater than a number of multi-level data states that were programmed at the plurality of memory cells; and
causing, while programming using the final programming pulse, an analog enable voltage level to be applied to bitlines coupled to the final subset of memory cells.

15. A method comprising:
causing, by control logic of a memory device, and in between applying programming pulses to selectively store data to multiple voltage levels of a plurality of memory cells:
a second occurrence of a first analog verify operation to be performed on a first set of memory cells to identify one or more memory cells of a first subset of the first set of memory cells, wherein the first subset of memory cells failed the first analog verify operation, and the one or more memory cells twice failed the first analog verify operation; and
a first occurrence of a second analog verify operation to be performed on a second set of memory cells to identify a second subset of the second set of memory cells that failed the second analog verify operation.

16. The method of claim 15, further comprising:
causing the first set of memory cells to be programmed using a first programming pulse, wherein the memory device comprises an array of a plurality of memory cells that includes the first set of memory cells;
causing a first occurrence of the first analog verify operation to be performed on the first set of memory cells to determine the first subset of memory cells that failed the first analog verify operation; and
causing the first subset of memory cells and a second set of memory cells to be programmed using a second programming pulse having a higher voltage level than the first programming pulse.

17. The method of claim 16, further comprising, while programming using the second programming pulse, causing an analog enable voltage level to be applied to bitlines, of a plurality of bitlines, associated with the first subset of memory cells.

18. The method of claim 16, further comprising causing the one or more memory cells of the first subset of memory cells, the second subset of memory cells, and a third set of memory cells to be programmed using a third programming pulse having a higher voltage than the second programming pulse.

19. The method of claim 18, further comprising, while programming using the third programming pulse:
causing a finalize analog voltage level to be applied to bitlines, of a plurality of bitlines, coupled to the one or more memory cells of the first subset of memory cells; and
causing an analog enable voltage level to be applied to bitlines, of the plurality of bitlines, coupled to the second subset of memory cells.

20. The method of claim 18, further comprising:
causing a second occurrence the second analog verify operation to be performed on the second set of memory cells to determine one or more memory cells of the second subset of memory cells that again failed the second analog verify operation; and
causing a third analog verify operation to be performed at the third set of memory cells to determine a third subset of the third set of memory cells that failed the third analog verify operation.

21. The method of claim 18, further comprising:
causing a final set of memory cells to be programmed using a penultimate programming pulse having a higher voltage than a preceding programming pulse;
causing a final analog verify operation to be performed at the final set of memory cells to determine a final subset of the final set of memory cells that failed the final analog verify operation;
causing the final subset of memory cells to be programmed using a final programming pulse, wherein the first programming pulse through the final programming pulse are numbered one greater than a number of multi-level data states that were programmed at the plurality of memory cells; and
causing, while programming using the final programming pulse, an analog enable voltage level to be applied to bitlines coupled to the final subset of memory cells.
